(19) United States
(12) Patent Application Publication
(10) Pub. No.: US 2015/0305202 A1
(43) Pub. Date: Oct. 22, 2015

(54) ADJUSTABLE AIRFLOW BARRIER SYSTEM

(71) Applicants: Clint Veino, Hampstead, NH (US); Bruce Long, Corrales, NM (US)

(72) Inventors: Clint Veino, Hampstead, NH (US); Bruce Long, Corrales, NM (US)

(21) Appl. No.: 14/660,105

(22) Filed: Mar. 17, 2015

Related U.S. Application Data
(63) Continuation of application No. PCT/US2015/020399, filed on Mar. 13, 2015.
(60) Provisional application No. 61/952,498, filed on Mar. 13, 2014.

(51) Int. Cl. H05K 7/20

(52) U.S. Cl. CPC H05K 7/20709

(57) ABSTRACT

An adjustable airflow barrier system has a roll of flexible sheet air barrier contained in a housing. The air barrier is biased in retracted position and has a range of extended positions. A pull bar is attached to a free edge of the air barrier. A first magnetic mount is coupled to the housing to removably mount the housing to a first support surface, such as a cabinet in a data center. A second magnetic mount is coupled to the pull bar to removably mount the pull bar to a second support surface spaced from the first support surface. The housing is operable to form a substantial air seal with the first support surface, and the pull bar is operable to form a substantial air seal with the second support surface.

### FIELD OF THE INVENTION

The present invention relates to airflow containment systems and, in particular, to airflow containment systems for data centers.

### BACKGROUND OF THE INVENTION

Modern data centers house large numbers of computer servers, typically housed in rows of server cabinets, in which a plurality of servers are mounted in a closely spaced relation within the cabinets. In operation, the densely arranged servers generate substantial heat, which must be removed in order to prevent overheating and malfunction of the equipment. The individual server units generally are provided with internal fans, which pull cooling air through the unit. However, because of the high density of the equipment, it is customary to provide substantial air conditioning systems to supply cooled air to the fronts of the cabinets, available to be drawn through the individual servers by their internal fans.

Operating efficiency of the cooling systems has become an increasing problem as the power output of the servers has been progressively increased and the expense of cooling them has become very meaningful. A significant aspect of controlling cooling costs is the prevention or minimization of mixing of the cooled air at the front of the cabinet, with warm air in the data center. Where mixing is allowed to occur outside of the servers, the capacity of the A/C equipment must be enlarged, at increased capital expense. In addition the efficiency of the NC equipment is compromised due to the lower temperature differential between the air returned to the A/C equipment.

Among the techniques employed at modern data centers to improve efficiency is arranging rows of server cabinets in hot- and cold-air aisles. Typically, two rows of server cabinets are oriented back-to-back, with cool air being supplied to the fronts of the rows (forming cold aisles) and warm air being collected in the hot aisle between the two rows, which is then returned to the A/C unit. This technique represents an improvement over previous arrangements but still permits considerable quantities of the cool air to bypass the servers and mix with warm air.

Other techniques employed in modern data centers are complete air containment (i.e., complete enclosure) and partial air containment. Complete air containment involves completely closing off an aisle, for example a cold-air aisle, between rows of server cabinets. In complete air containment, roof baffles are connected between the top portions of adjacent rows of server cabinets, to create an upper barrier, and doors (or walls) are connected between side potions of the cabinets at the ends of adjacent rows, to create side barriers. The floor of the server room and the cabinets provide the remaining sides of the complete enclosure. In a cold-air aisle, for example, perforations in the floor panels allow air to flow into the enclosed cold-air aisle and then to the servers.

In partial air containment systems, the system does not completely enclose the area between adjacent rows of cabinets. The purpose and intention of partial air containment systems is to inhibit undesirable airflow, but at the same time provide benefits of an open aisle configuration.

### SUMMARY OF THE INVENTION

The adjustable airflow barrier system of the invention provides a tool-less, modular and reusable air containment system designed, and particular suitable for, modern data centers. The system is highly configurable and effectively isolates hot and cold air mixing between adjacent hot- and cold-air aisles in an efficient and cost-effective manner.

The adjustable airflow barrier system includes an air barrier preferably formed of a flexible sheet entirely or substantially impermeable to air, which is wound in a roll and biased in a retracted (wound) position. A pull bar is connected to a free edge of the air barrier to extend (unwind) the air barrier. A first magnetic mount coupled to the roll is operable to removably mount the roll to a first support surface, and a second magnetic mount coupled to the pull bar is operable to removably mount the pull bar to a second support surface, spaced from the first support surface. The pull bar is operable to exert tension on the air barrier to maintain the air barrier in a flat shape.

The airflow barrier system can be placed between two equipment cabinets in a row of cabinets in a data center, with the roll in a vertical orientation, to close a gap between the cabinets which can occur, for example, when a support column or other structure prevents cabinets from being placed in a contiguous row. Alternatively, the airflow barrier system can also be placed in a gap between a cabinet and adjacent support column, between two support columns, or between two cabinets in opposing rows of cabinets, such as two end cabinets, to divide or close off an aisle. Additionally, the airflow barrier system can be placed between the tops of two cabinets in opposing rows, to create an aisle ceiling, and other implementations. The airflow barrier system preferably spans the entire width (gap) between the spaced-apart structures supporting it (e.g., cabinets, structural columns, etc.) and extends the full height of the cabinets to inhibit airflow into and out of the aisle to reduce undesirable mixing of cooling and hot airflows.

The adjustable airflow barrier system has an air barrier comprising a flexible sheet; the air barrier being biased in a retracted position wherein the air barrier is substantially wound in a roll; the roll being contained in a housing; the air barrier having a range of extended positions wherein the air barrier is at least partially unwound from the roll; the air barrier having a free edge, and a pull bar attached to the free edge; a first magnetic mount coupled to the housing and operable to removably mount the housing to a first support surface; a second magnetic mount coupled to the pull bar and operable to removably mount the pull bar to a second support surface spaced from the first support surface, with the air barrier in an extended position; the housing being operable to form a substantial air seal with the first support surface; and the pull bar being operable to form a substantial air seal with the second support surface.

The first magnetic mount can comprise a first magnet affixed to the housing and the second magnetic mount comprises a second magnet affixed to the pull bar. The housing can have an opening on a first side thereof; and the air barrier passing through the opening.

The first magnet can be disposed on a second side of the housing opposite the first side thereof; and the free edge of the air barrier extending from a first side of the pull bar and the second magnet being disposed on a second side of the pull bar opposite the first side thereof.

The pull bar can have a third side between the first and second sides thereof; the pull bar including a first grip extending outwardly from the third side thereof; and the first grip being spaced from the second side of the pull bar a distance sufficient to permit a user to grasp the grip when the second side of the pull bar is connected to the second support surface.

The pull bar can have a fourth side between the first and second sides thereof, opposite the third side; the pull bar including a second grip extending outwardly from the fourth side thereof; and the second grip being spaced from the second side of the pull bar a distance sufficient to permit a user to grasp the grip when the second side of the pull bar is connected to the second support surface.

The first magnet can be disposed on a third side of the housing adjoining the first side thereof; and the free edge of the air barrier extending from a first side of the pull bar and the second magnet being disposed on a third side of the pull bar adjoining the first side. The first magnetic mount can further comprise a ferromagnetic plate affixed to the first support surface.

The airflow barrier system can further comprise a data center having a plurality of equipment cabinets; the first support surface being a vertical surface of a first one of the plurality of equipment cabinets; and the housing being removably mounted to the first support surface by the first magnetic mount. The second support surface can be a vertical surface of a second one of the plurality of equipment cabinets; and the pull bar is removably mounted to the second support surface by the second magnetic mount. The first and second equipment cabinets can be in a row of equipment cabinets; a gap exists between the first and second equipment cabinets; and the air barrier spans the gap between the first and second equipment cabinets.

The first equipment cabinet can be in a first row of equipment cabinets with the second equipment cabinet in a second row of equipment cabinets; an aisle is disposed between the first and second rows of equipment cabinets; and the air barrier spans a width of the aisle.

The housing and pull bar can be operable to support the air barrier on a horizontal surface in a vertical orientation, wherein a gap between the horizontal surface and a lower edge of the air barrier is less than 2 inches.

A coil spring can be operable to bias the roll into the retracted position and to maintain tension in the air barrier in an extended position.

The housing can be operable to removably mount to a planar portion of the first support surface; and the pull bar is operable to removably mount to a planar portion of the second support surface.

An adjustable cap can be operable to cover a top edge of the air barrier in an extended position; and the cap comprising first and second telescoping portions each having a vertical lower portion, a horizontal upper portion and a magnetic mount operable to removably mount to the first and second support structures.

### BRIEF DESCRIPTION OF THE DRAWINGS

FIG. 1 is a perspective view of a first embodiment of an adjustable airflow barrier system constructed in accordance with the invention, shown in an extended position installed in a gap between two equipment cabinets in a row of cabinets in a data center environment;

FIG. 2 is a front view of the adjustable airflow barrier system of FIG. 1;

FIG. 3 is a top view of the adjustable airflow barrier system of FIG. 1;

FIG. 4 is an enlarged cross-sectional view of the airflow barrier system, taken along a right-hand portion of line A-A in FIG. 2, showing the housing and air barrier roll contained therein mounted to a support structure;

FIG. 5 is an enlarged cross-sectional view of the airflow barrier system, taken along a left-hand portion of line A-A in FIG. 2, showing the pull bar and grip mounted to a support structure;

FIG. 6 is a perspective view of the airflow barrier system of FIG. 1, shown in an extended position, without support structures;

FIG. 7 is a front view of the airflow barrier system of FIG. 6;

FIG. 8 is a left side view of the airflow barrier system of FIG. 6;

FIG. 9 is a right side view of the airflow barrier system of FIG. 6;

FIG. 10 is a perspective view of a cap for the airflow barrier system of FIG. 1;

FIG. 11 is a perspective view of the airflow barrier system of FIG. 1, shown in an extended position installed in a gap between two equipment cabinets in adjacent rows of cabinets in a data center environment; and

FIG. 12 is a top view of the adjustable air barrier system of FIG. 10.

### DETAILED DESCRIPTION OF THE INVENTION

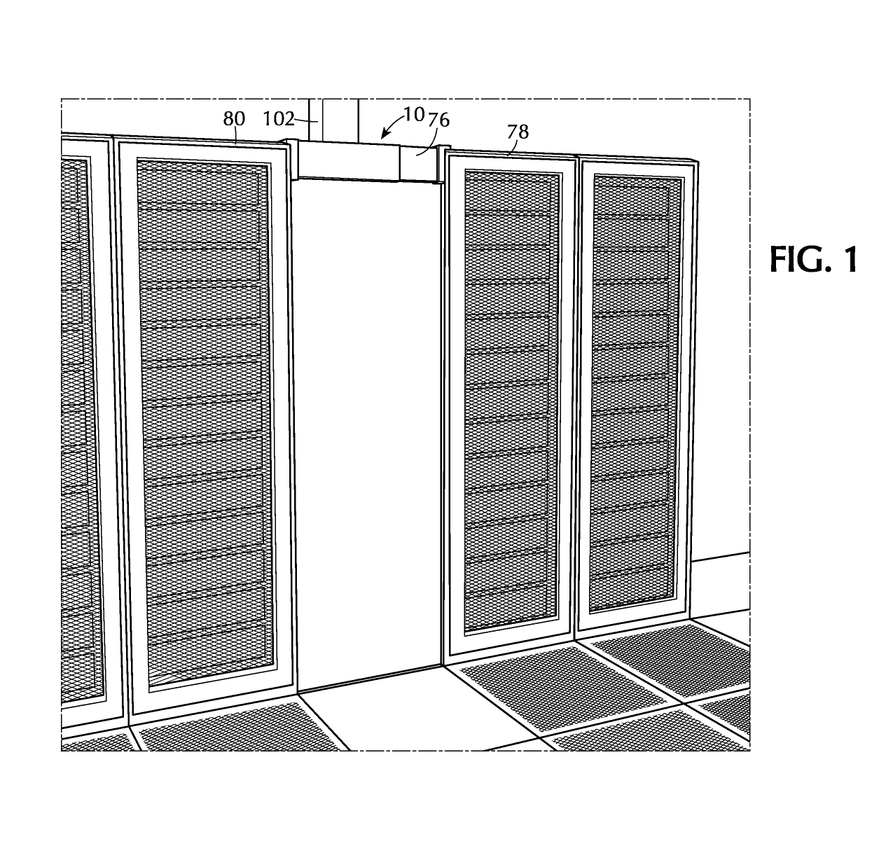

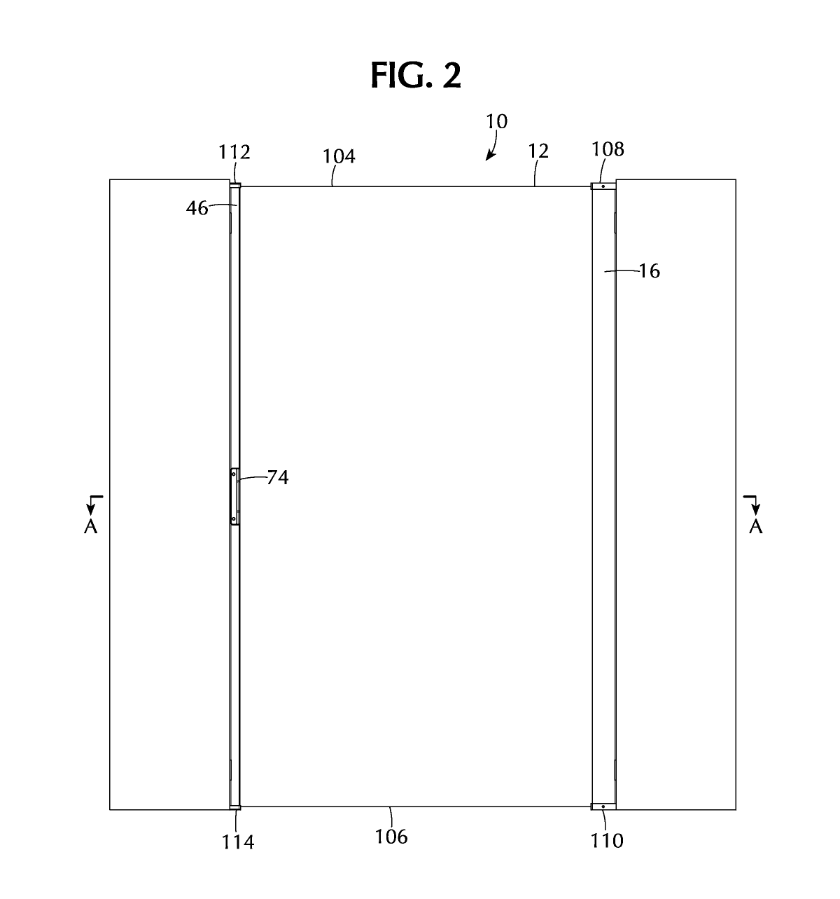

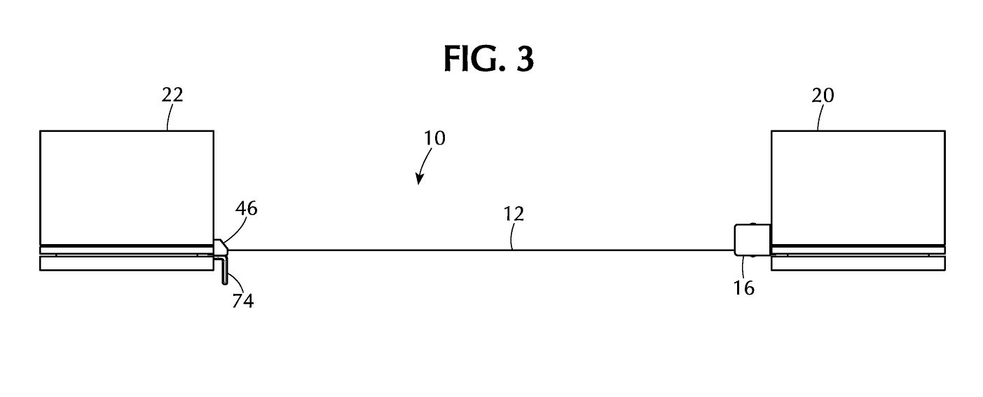

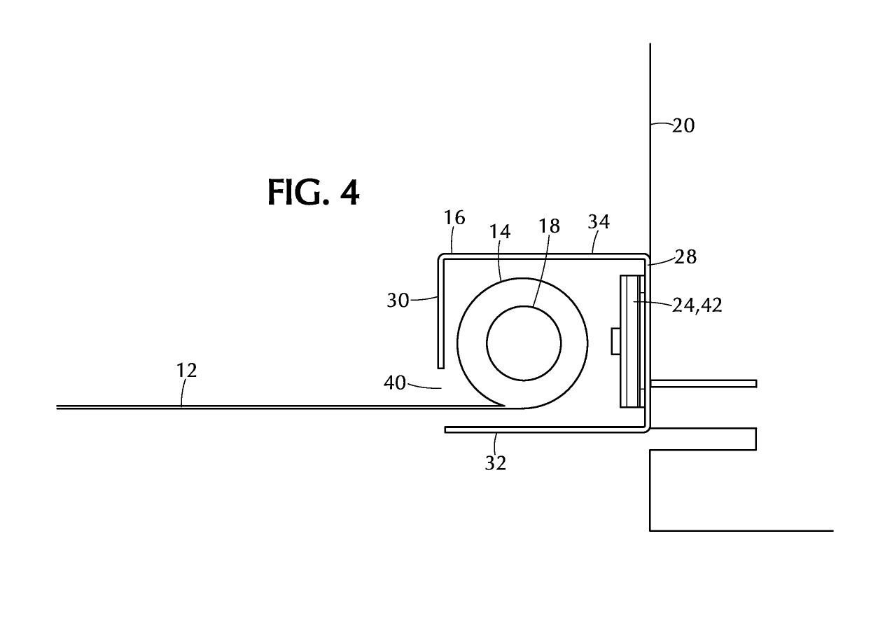

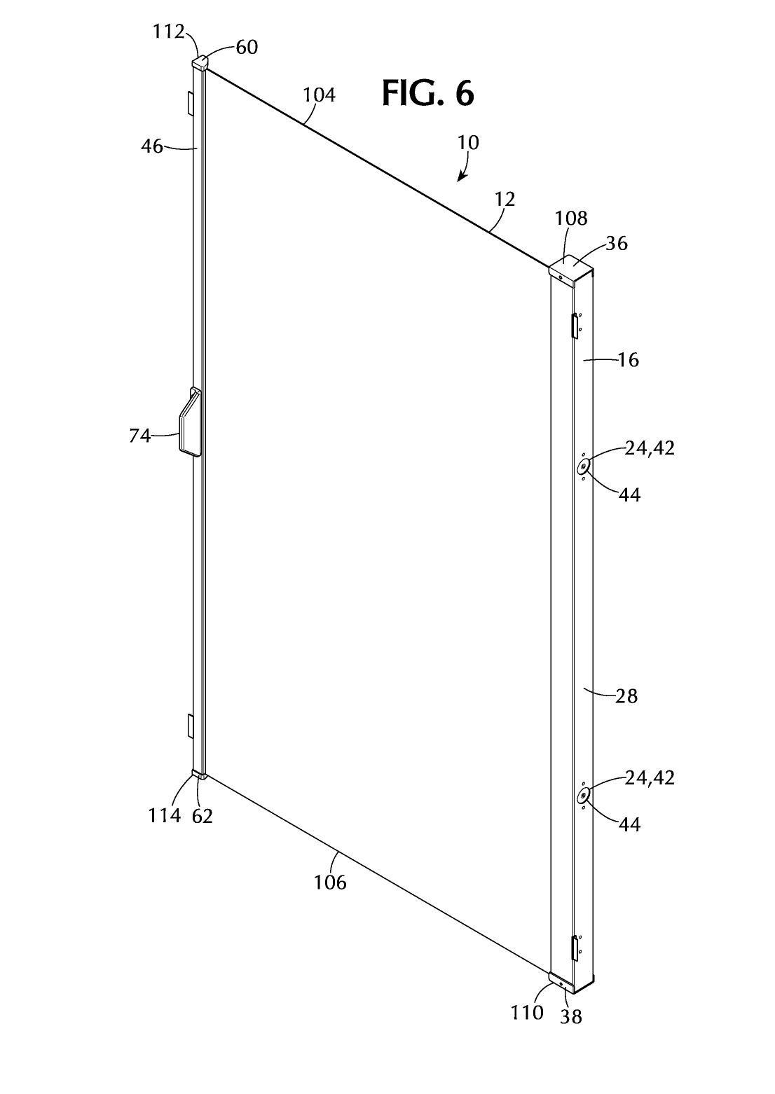

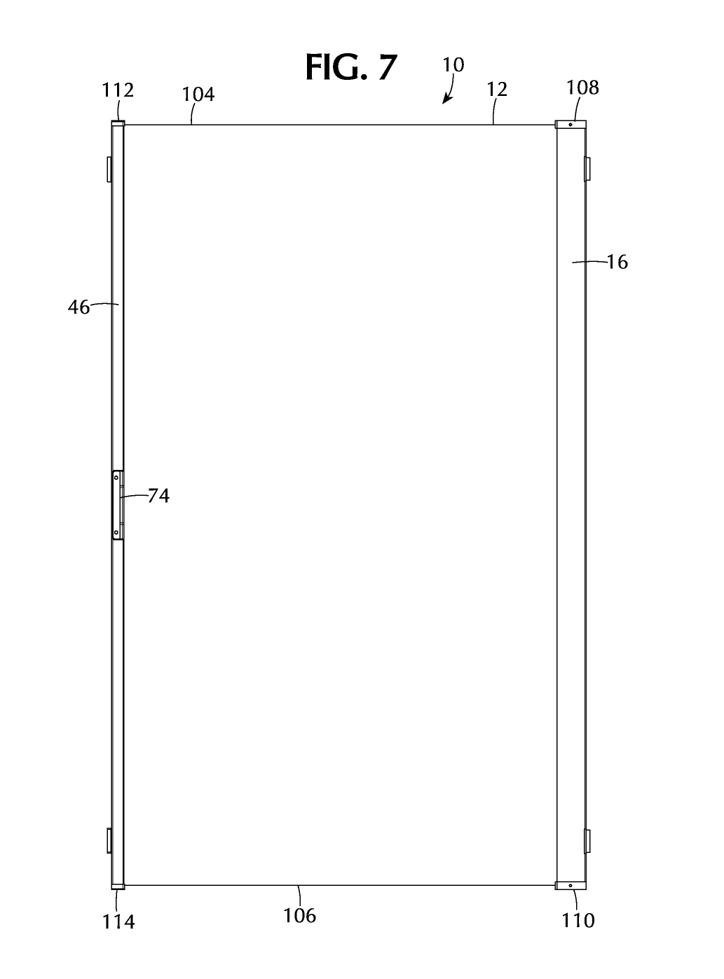

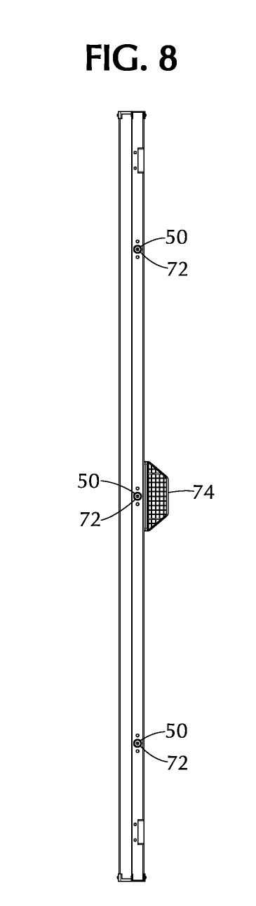

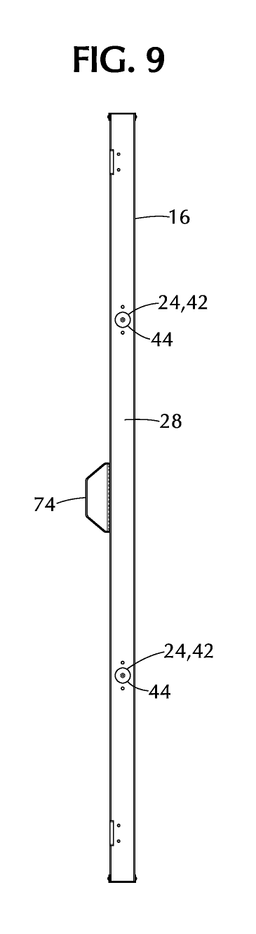

Referring to FIGS. 1-12, the adjustable airflow barrier system 10 includes an air barrier 12 preferably formed of a flexible sheet that is entirely or substantially impermeable to air. The air barrier 12 is wound in a roll 14 (See FIG. 4) which is rotatably mounted inside an elongated housing 16, which may include flanges or other supporting structure rotationally supporting the roll. The roll 14 is biased into a retracted position (i.e., wound) to store the air barrier 12 in the housing 16 when not in use and to hold the air barrier 12 taught during use. For example, a coil spring 18 contained within and/or connected to the housing 16 and the roll 14 can bias the roll 14 in the retracted (wound) position. Preferably the bias does not include a ratchet or other locking mechanism such that the air barrier 12 is maintained in tension at all times.

The airflow barrier system can be placed between two equipment cabinets 78, 80 in a row of cabinets in a data center, with the roll in a vertical orientation, to close a gap between the cabinets which can occur, for example, when a support column 102 or other structure prevents cabinets from being placed in a contiguous row (See FIG. 1). Alternative uses also exist. For example, the airflow barrier system can also be placed in a gap between a cabinet and adjacent support column, between two support columns, or between two cabinets in opposing rows of cabinets, such as two end cabinets, to divide or close off an aisle, but not limited thereto.

The air barrier 12 can be formed of or include a flame rated fabric material. For example, the fabric material can be a 0.30 mm thick fiberglass-based laminated PVC material, which meets or exceeds the NFPA-701 flame retardant standard. Alternatively, or additionally, the material can consists of or comprise a translucent or transparent portion, such as clear vinyl, or can include windows or other openings. Further, the material can be designed to resist wrinkles and remain flat.

The air barrier 12 preferably has a height substantially equal to the height of the equipment cabinets, and extends from the bottom of the cabinet to the top. Ideally the height of the air barrier 12 is within +/−0.5 inches of the height of the cabinet. For example, for a typical 42U cabinet, the height of the air barrier 12 should be 79.75+/−0.5 inches; for a 45U cabinet, 85+/−0.5 inches; for a 48U cabinet, 90.25+/−0.5 inches, and for a 50U cabinet, 93.75+/−0.5 inches. The (horizontal) width of the air barrier is preferably infinitely adjustable between a minimum and maximum width, for example from about 12″ to about 60″ or 72″ inches, or more, to accommodate gaps of various widths.

The housing 16 is adapted to removably mount to a support surface 20, such as the vertical, planar side surface of a server cabinet, adjacent the front of the cabinet, or to other structures, with the rolled air barrier aligned vertically. The housing 16 includes one or more magnetic mounts 24 for removably mounting the housing 16 to a ferromagnetic surface, such as a metal server cabinet or other metallic structure or surface, without the need for tools.

The housing 16 can be a hollow enclosure (See FIG. 4), for example in the form of a substantially enclosed rectilinear channel, and can have an elongated rectangular base wall 28 and opposed front wall 30, opposed parallel side walls 32, 34 adjoining the base and front walls, and two end walls 36, 38 forming end caps for the channel. The front wall 30 includes a slot or opening 40 substantially along the entire length thereof through which the air barrier 12 extends.

The housing 16 is preferably substantially the same height as the air barrier 12, as discussed above, but may be slightly longer (about 1 inch longer) to accommodate the presence of end caps 108, 110 of the housing 16. The base wall 28 of the housing 16 preferably includes a planar surface along the length which contacts and abuts the typically planar support surface 20 during use.

The magnetic mounts 24 of the housing 16 can include one or more magnets 42 affixed to the housing 16. The magnets 42 are recessed or contained within the housing 16 and preferably extend at least partially through openings 44 in the base wall 28 sized and shaped to receive the magnets 42.

An elongated, rigid pull bar 46, such as a metal or plastic rail or the like, is connected to a free edge 48 of the air barrier 12 (opposite the edge connected to the roll 14), preferably along the entire height of the air barrier 12, to retract/unwind the air barrier 12 into an extended position and to support the air barrier during use. The pull bar 46 is operable to exert tension along substantially the entire free edge 48 of the air barrier 12 to maintain the air barrier 12 in flat configuration during use. Preferably, the pull bar 46 is sized and shaped such that it does not fit through the opening 40 in the housing 16 thereby preventing the air barrier 12 from fully winding on the roll 14. Preferably, the coil spring 18 (or other bias means) is sufficiently pre-tensioned during assembly of the airflow barrier system 10 such that, except for the pull bar 46 and the free edge 48 portion of the air barrier 12 retained thereby, the air barrier 12 is fully wound on the roll 14 when not in use.

The pull bar 46 is adapted to removably mount to a support surface 22, such as the vertical, planar side surface of a server cabinet, adjacent the front of the cabinet, or to other structures, with the pull bar 46 aligned vertically. The pull bar 46 includes one or more magnetic mounts 50 for removably mounting the pull bar 46 to a ferromagnetic surface, such as a metal server cabinet or other metallic structure or surface, without the need for tools, to maintain the air barrier 12 in place during use.

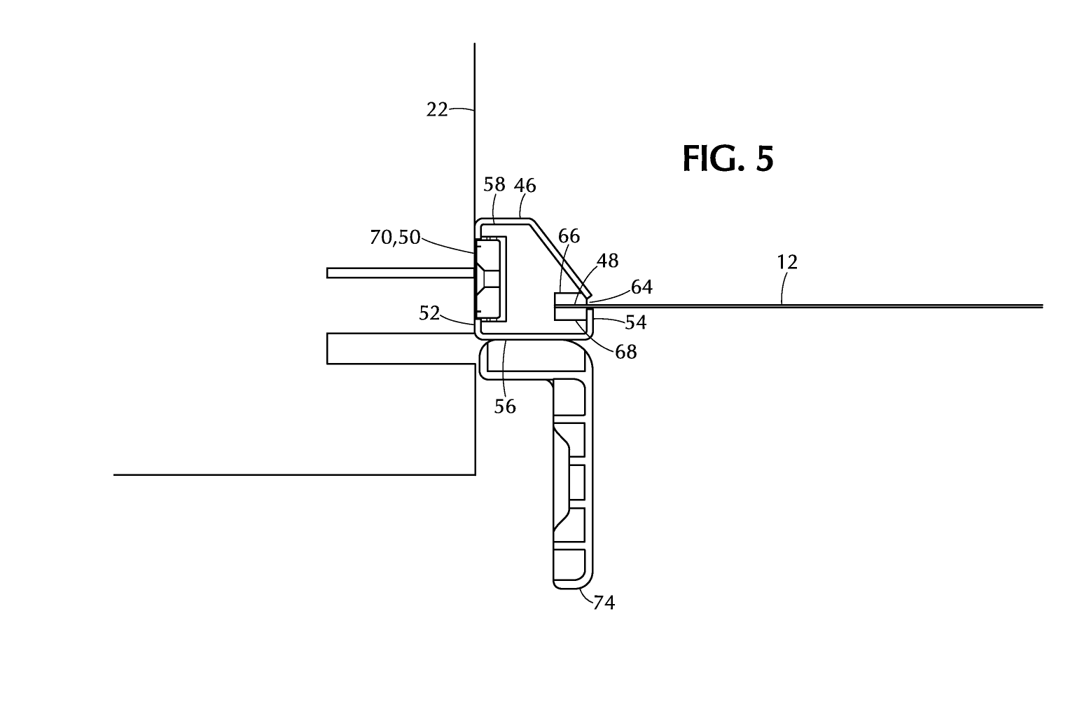

The pull bar 46 can be a hollow enclosure (See FIG. 5), for example in the shape of a substantially enclosed rectilinear channel, and can include an elongated rectangular base wall 52 and opposed front wall 54, opposed parallel side walls 56, 58 adjoining the base wall and front wall, and two end walls 60, 62 forming end caps for the channel. The front wall 54 includes a slot or opening 64 along the length thereof, through which the free edge 48 of the air barrier 12 extends. The free edge 48 of the air barrier is connected to the rigid bar 48, preferably by a pair of capture elements 66, 68 or the like affixed to opposing sides of the free edge 48 of the air barrier 12 within the pull bar 46. The capture elements 66, 68 are sized and shaped such that they will not fit through the opening 64 in the front wall 54 of the pull bar 46 and thus retain the free edge 48 of the air barrier 12 in the pull bar 46.

The pull bar 46 is preferably substantially the same height as the housing 16. That is, the pull bar 46 may be substantially the same height as the air barrier 12, as discussed above, but may be slightly longer to accommodate the presence of end caps 112, 114 of the pull bar 46. The base wall 52 of the pull bar 46 opposite the preferably includes a planar surface along the length which contacts and abuts the typically planar support surface 22 during use.

The base wall 52 of the pull bar 46, opposite the front wall 54, has a planar surface along the length which contacts and abuts the typically planar support surface 22. The magnetic mount 50 of the pull bar 46 can include one or more magnets 70 affixed to the pull bar 46. The magnets 70 are recessed or contained within the pull bar 46 and preferably extend at least partially through openings 72 in the base sized and shaped to receive the magnets 70.

The pull bar 46 and/or air barrier 12 can include a grip 74 intermediate top 104 and bottom 106 edges of the air barrier 12. The grip 74 extends horizontally outwardly from a side wall 56 of the pull bar 46. The grip 74 is spaced from a plane of the base wall 52 of the pull bar 46 a distance sufficient to permit a user to grasp the grip 74 when the base wall 52 is connected to a support surface 22, such as a server cabinet, for example about 1 to about 3 inches. The pull bar 46 can include a second grip (not shown) on the opposing side wall 58 with a similar configuration such that the airflow barrier system 10 can installed in the opposite direction (e.g., left to right, as opposed to right to left, as depicted).

The housing 16 and pull bar 46 are preferably operable to support the roll 14 very close to a horizontal surface, such as a floor, in a vertical orientation, wherein a gap between the horizontal surface and a lower edge 106 of the air barrier is less than 2 inches, and more preferably less than 1 inch, or less than 0.5 inches.

Preferably, the housing 16, for example the base wall 28 of the housing 16, includes and/or makes a substantial air seal against the cabinet or other support surface 20 to which it is connected along the entire length (i.e., vertical height, when oriented vertically) of the housing 16 to prevent or inhibit airflow between the housing 16 and the support surface 20. For example, the base wall 28 of the housing 16 can be substantially planar, with the magnets 42 disposed thereon recessed from the plane of the base wall 28. Further, the support surface 20 is preferably planar. Therefore, when the housing 16 is mounted on the support surface 20, a substantial air seal is formed therebetween. In addition, due to the configuration of the housing 16, and in particular the fact that the air barrier 12 enters the housing 16, a substantial air seal is formed between the air barrier 12 and the housing 16, substantially along the entire length of the housing 16. The housing 16 can include a flexible or variable-width seal which maintains contact with the roll 14 and/or the air barrier 12 along the length thereof to inhibit airflow between the roll 14 and the housing 16 at all times.

As with the housing 16, the pull bar 46, for example the base wall 52 of the pull bar 46, can include and/or make or form a substantial air seal against the opposing cabinet or support surface 22 along the entire length (i.e., vertical height, when oriented vertically) of the pull bar 46 to prevent or inhibit airflow between the free edge 48 of the air barrier 12 and the opposing support surface 20. The base wall 52 of the pull bar 46 can be substantially planar, with the magnets 70 disposed thereon recessed from the plane of the base wall 52. Further, the support surface 22 is preferably planar. Therefore, when the pull bar 46 is mounted on the support surface 22, a substantial air seal is formed therebetween. In addition, due to the configuration of the pull bar 46, and in particular the fact that the air barrier 12 enters the pull bar 46, a substantial air seal is formed between the air barrier 12 and the pull bar 46, substantially along the entire length of the pull bar 46. Thus, when the airflow barrier system 10 is installed a substantial air seal is formed spanning the gap between the support surfaces 20, 22, from the floor to the top of the cabinets, to prevent undesired airflow into the gap area.

Optionally, the airflow barrier system 10 can include metallic or ferromagnetic striker plates for magnetically mounting the housing 16 and pull bar 46 to non-metallic structures, such as concrete support columns and similar structures. The striker plates can be mechanically mounted to such non-metallic structures, with mechanical fasteners or adhesives or the like. The striker plates can be positioned to engage, on one side of the gap, the magnetic mounts 26 of the housing 16, and on the other side of the gap, the magnetic mounts 50 of the pull bar 46, as required.

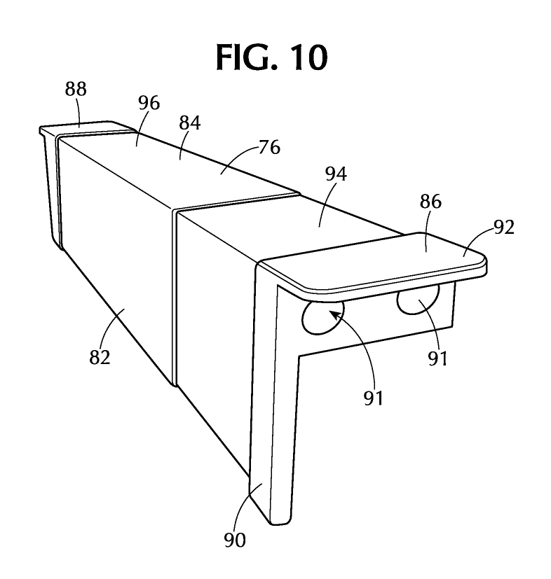

Referring to FIGS. 1 and 10, the airflow barrier system 10 can include an adjustable cap 76 to cover the otherwise exposed top edge of the air barrier 12 between the housing 16 and the pull bar 46 when in an extended position. For example, a cap 76 can mount to the tops of the adjacent (spaced-apart) server cabinets 78, 80 or other support structure. The cap 76 performs several functions: it provides an enhanced air seal at the top of the air barrier 12, it provides a platform for mounting other structures, and it allows for variance between the height of the air barrier 12 and the height of the cabinets 78, 80.

A front portion 82 of the cap 76 covers the top edge of the air barrier 12 when in use and a top portion 84 of the cap 76 extends horizontally from an upper edge of the front portion 82, toward a rear of the cabinets 78, 80. Thus, a vertical cross-section of the cap 76, taken perpendicular to the air barrier 12, is a substantially inverted L shape. The cap 76 can also include a pair of end brackets 86, 88, each having a vertically-aligned base portion 90 and a mounting flange 92 extending horizontally laterally-outwardly from the base portion 90 for supporting the cap 76 on adjacent cabinets. The mounting flanges 92 are adapted to contact and rest on the tops of the adjacent cabinets 78, 80. The base portions 90 can also include magnets 91 disposed below the mounting flanges 92 for removably mounting the cap 76 to the sides of the cabinets.

Preferably, the width of the cap 76 is adjustable to accommodate gaps of various widths. The cap 76 can be formed of two complementary, nested or telescoping halves 94, 96 of substantially inverted L-shaped cross section, each having one of the aforementioned end brackets 86, 88. The telescoping halves 94, 96 are preferably slidably connected together and can retract and extend to accommodate any gap width between the minimum and maximum widths.

As depicted, the air barrier 12 is particularly suitable for mounting to the vertical support surface 20, 22, such as the side of a server cabinet or other structure, with the air barrier 12 in a vertical orientation. However, it is within the scope of the invention to align the air barrier 12 in a horizontal orientation to, for example, form a ceiling over an aisle.

Preferably, the airflow barrier system 10 is reversible such that it can be mounted on the left side of gap and drawn to the right, or it can be mounted on the right side of a gap and drawn left. As disclosed herein, the grip 74 of the pull bar 46 can extend horizontally on both sides of the pull bar 46 such that the grip is accessible in either orientation. Additionally, the air barrier 12 (or the housing or pull bar) can have substantially different colors on opposite sides, such as a dark or black color on one side and a light or white color on the opposite side such that the panel can be reversed to reveal the different colors as desired.

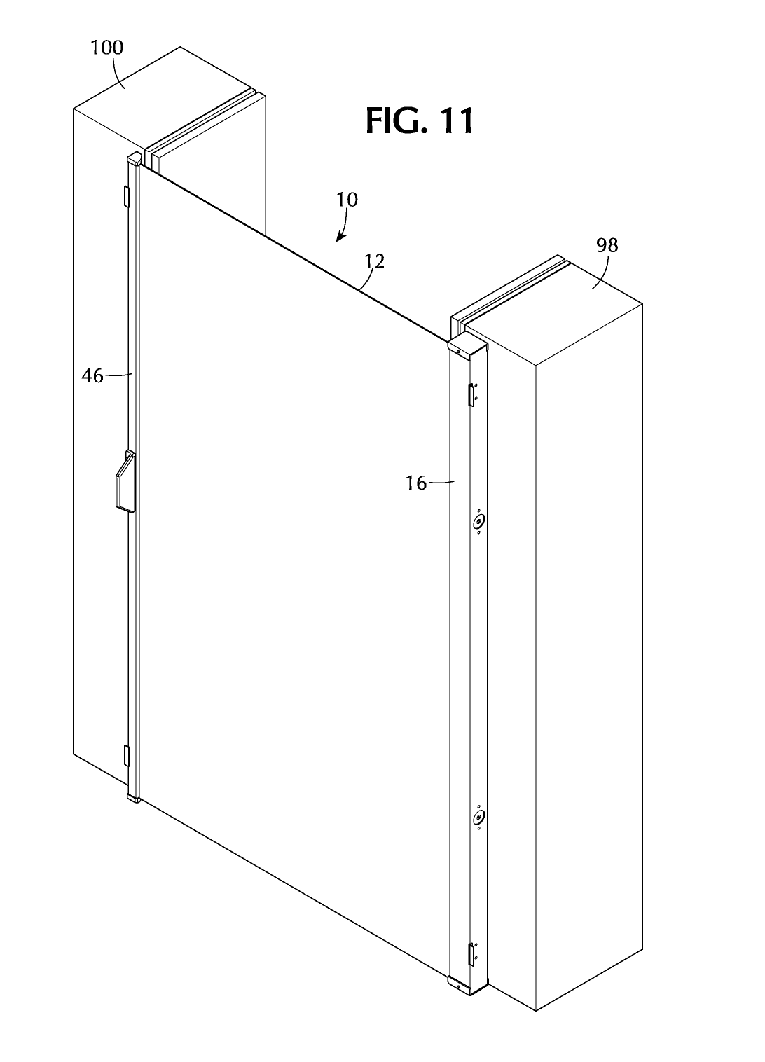

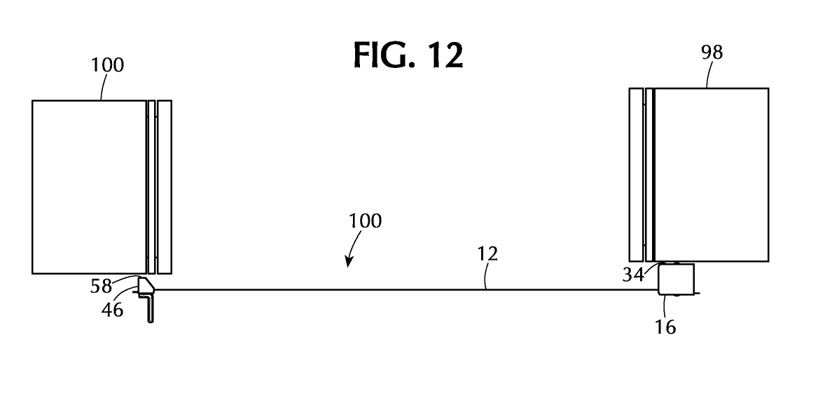

Referring to FIGS. 11 and 12, optionally, the airflow barrier 10 can be mounted between two end cabinets 98, 100 located at the ends of opposing rows of cabinets, or to other like structures, to close off the aisle therebetween. In this configuration, side walls 34, 58 of the housing 16 and pull bar 46 contact the cabinets. Therefore, instead of or in addition to the magnetic mounts 24, 50 disposed on the base walls 28, 52 of the housing 16 and pull bar 46 (as discussed above), the magnetic mounts 24, 50 can be disposed on the side walls 34, 58 of the housing 16 and pull bar 46, in a similar manner, to facilitate the alternative mounting configuration. A similar arrangement can be used to mount the airflow barrier system 10 to or between other support structures, such as support columns, or to tops of opposed cabinets.

It should be understood, of course, that the specific form of the invention herein illustrated and described is intended to be representative only, as certain changes may be made therein without departing from the clear teachings of the disclosure. Accordingly, reference should be made to the following appended claims in determining the full scope of the invention.

What is claimed is:

1. An adjustable airflow barrier system comprising:
an air barrier comprising a flexible sheet;
the air barrier being biased in a retracted position wherein the air barrier is substantially wound in a roll;
the roll being contained in a housing;
the air barrier having a range of extended positions wherein the air barrier is at least partially unwound from the roll;
the air barrier having a free edge, and a pull bar attached to the free edge;
a first magnetic mount coupled to the housing and operable to removably mount the housing to a first support surface;
a second magnetic mount coupled to the pull bar and operable to removably mount the pull bar to a second support surface spaced from the first support surface, with the air barrier in an extended position;
the housing being operable to form a substantial air seal with the first support surface; and
the pull bar being operable to form a substantial air seal with the second support surface.

2. An adjustable airflow barrier system, as in claim 1, wherein:
the first magnetic mount comprises a first magnet affixed to the housing and the second magnetic mount comprises a second magnet affixed to the pull bar.

3. An adjustable airflow barrier system, as in claim 2, further comprising:
the housing having an opening on a first side thereof; and
the air barrier passing through the opening.

4. An adjustable airflow barrier system, as in claim 3, further comprising:
the first magnet being disposed on a second side of the housing opposite the first side thereof; and
the free edge of the air barrier extending from a first side of the pull bar and the second magnet being disposed on a second side of the pull bar opposite the first side thereof.

5. An adjustable airflow barrier system, as in claim 4, further comprising:
the pull bar having a third side between the first and second sides thereof;
the pull bar including a first grip extending outwardly from the third side thereof; and
the first grip being spaced from the second side of the pull bar a distance sufficient to permit a user to grasp the grip when the second side of the pull bar is connected to the second support surface.

6. An adjustable airflow barrier system, as in claim 5, further comprising:
the pull bar having a fourth side between the first and second sides thereof, opposite the third side;
the pull bar including a second grip extending outwardly from the fourth side thereof; and
the second grip being spaced from the second side of the pull bar a distance sufficient to permit a user to grasp the grip when the second side of the pull bar is connected to the second support surface.

7. An adjustable airflow barrier system, as in claim 3, further comprising:
the first magnet being disposed on a third side of the housing adjoining the first side thereof; and
the free edge of the air barrier extending from a first side of the pull bar and the second magnet being disposed on a third side of the pull bar adjoining the first side.

8. An adjustable airflow barrier system, as in claim 2, wherein:
the first magnetic mount further comprises a ferromagnetic plate affixed to the first support surface.

9. An adjustable airflow barrier, as in claim 1, further comprising:
a first support surface and a second support surface;
the housing being removably mounted to the first support surface by the first magnetic mount and the housing forming a substantial air seal with the first support surface; and
the pull bar being removably mounted to the second support surface by the second magnetic mount and the pull bar forming a substantial air seal with the second support surface.

10. An adjustable airflow barrier system, as in claim 9, further comprising:
a data center having a plurality of equipment cabinets; and
the first support surface being a vertical surface of a first one of the plurality of equipment cabinets.

11. An adjustable airflow barrier system, as in claim 10, wherein:
the second support surface is a vertical surface of a second one of the plurality of equipment cabinets.

12. An adjustable airflow barrier system, as in claim 11, wherein:
the first and second equipment cabinets are in a row of equipment cabinets;
a gap exists between the first and second equipment cabinets; and
the air barrier spans the gap between the first and second equipment cabinets.

13. An adjustable airflow barrier system, as in claim 11, wherein:
the first equipment cabinet is in a first row of equipment cabinets and the second equipment cabinet is in a second row of equipment cabinets;
an aisle is disposed between the first and second rows of equipment cabinets; and
the air barrier spans a width of the aisle.

14. An adjustable airflow barrier system, as in claim 3, wherein:
the housing and pull bar are operable to support the air barrier on a horizontal surface in a vertical orientation, wherein a gap between the horizontal surface and a lower edge of the air barrier is less than 2 inches.

15. An adjustable airflow barrier system, as in claim 1, further comprising:
a coil spring operable to bias the roll into the retracted position and to maintain tension in the air barrier in an extended position.

16. An adjustable airflow barrier system, as in claim 1, wherein:
the housing is operable to removably mount to a planar portion of the first support surface; and
the pull bar is operable to removably mount to a planar portion of the second support surface.

17. An adjustable air barrier system, as in claim 1, further comprising:
an adjustable cap operable to cover a top edge of the air barrier in an extended position; and
the cap comprising first and second telescoping portions each having a vertical lower portion, a horizontal upper portion and a magnetic mount operable to removably mount to the first and second support structures.
